(19) United States
(12) Patent Application Publication
(10) Pub. No.: US 2026/0246452 A1
(43) Pub. Date: Aug. 20, 2026

(54) MULTI-LEVEL DIGITAL STEP ATTENUATOR AND DIGITAL STEP ATTENUATION DEVICE

(71) Applicant: MEDIATEK INC., Hsinchu City (TW)

(72) Inventors: Wei-Hsin TSENG, Hsinchu City (TW); Jhen-Kai WANG, Hsinchu City (TW)

(21) Appl. No.: 19/646,861

(22) Filed: Apr. 14, 2026

Related U.S. Application Data
(63) Continuation of application No. 18/395,930, filed on Dec. 26, 2023, now Pat. No. 12,627,281.
(60) Provisional application No. 63/480,314, filed on Jan. 18, 2023.

(51) Int. Cl. H03H 17/00; H03H 7/25; H03H 11/24

(52) U.S. Cl. CPC H03H 17/0054; H03H 7/25; H03H 11/24

(57) ABSTRACT

A multi-level digital step attenuator includes an input node, an output node, a hybrid attenuation circuit, and a bypass switch. The hybrid attenuation circuit includes a series circuit portion coupled between the input and output nodes. In a first active state, the hybrid attenuation circuit is switched to form a T-type structure using the series circuit portion and a first shunt unit to provide a first amount of signal attenuation. In a second active state, the hybrid attenuation circuit is switched to form a Pi-type structure using the same series circuit portion and a second shunt unit to provide a second amount of signal attenuation. The active states share the series circuit portion as a signal attenuation path. A digital step attenuation device includes multiple stages, and is implemented by the hybrid multi-level digital step attenuator and is controlled by a 2-bit control signal to provide three attenuation states.

### CROSS REFERENCE TO RELATED APPLICATIONS

This application is a continuation of pending U.S. patent application Ser. No. 18/395,930, filed Dec. 26, 2023, which claims the benefit of U.S. Provisional Application No. 63/480,314, filed Jan. 18, 2023, the entirety of which is incorporated by reference herein.

### BACKGROUND OF THE INVENTION

### FIELD OF THE INVENTION

The present invention relates to a digital step attenuation technology.

### DESCRIPTION OF THE RELATED ART

In radio signal (RF) applications, a digital step attenuator (DSA) is a device that attenuates or reduces the amplitude of the RF signal that passes through it. The channel gain of the wireless receiver or transmitter (Rx/Tx), therefore, can be well controlled. The accuracy of the DSA will affect the reliability of the gain range of the channel, and therefore determine the usability of the Rx/Tx.

Generally, the amount of attenuation is controlled digitally. A conventional DSA can be digitally switched between two modes. In an attenuation mode, the RF signal is attenuated by an attenuation circuit of the DSA. In a normal bypass mode, the RF signal is allowed to pass through by a bypass switch rather than by the attenuation circuit.

Multiple DSAs may be coupled in series to provide more levels of signal attenuation. However, more stages may require more complex LC matching networks for wideband impedance matching.

How to reduce the number of DSA stages is an important topic in this field of technology.

### BRIEF SUMMARY OF THE INVENTION

A multi-level digital step attenuator (DSA) with a single bypass switch and a hybrid attenuation circuit is shown.

A multi-level digital step attenuator (DSA) with a hybrid attenuation circuit is disclosed. The hybrid attenuation circuit includes a series circuit portion coupled between an input node and an output node of the multi-level DSA. A bypass switch is controlled to provide a bypass path when the hybrid attenuation circuit is in a disabled state. In a first active state, the hybrid attenuation circuit forms a T-type structure with the series circuit portion to provide a first amount of signal attenuation. In a second active state, the hybrid attenuation circuit forms a Pi-type structure with the same series circuit portion to provide a second amount of signal attenuation. Hardware reuse is achieved as the first and second active states share the series circuit portion as a signal attenuation path, allowing for reduced circuit area and improved impedance matching.

Also disclosed is a digital step attenuation device comprising multiple stages of digital step attenuation units, with at least one stage implemented by the hybrid multi-level DSA. The hybrid stage is controlled by a 2-bit control signal to provide three states, integrated as a 1.5-bit attenuation stage. Compared to conventional designs, fewer stages are required for wide-range and high-resolution attenuation. This architecture reduces the total number of stages while providing more attenuation levels than conventional digital step attenuation devices having the same number of stages, thereby improving area efficiency and reducing insertion loss.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 depicts a multi-level digital step attenuator (DSA) 100 in accordance with an exemplary embodiment of the disclosure;

FIG. 2 depicts a multi-level DSA 200 in accordance with an exemplary embodiment of the disclosure;

FIG. 3 depicts a multi-level DSA 300 in accordance with another exemplary embodiment of the disclosure shows; and

FIG. 4 depicts a digital step attenuation device 400 in accordance with an exemplary embodiment of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

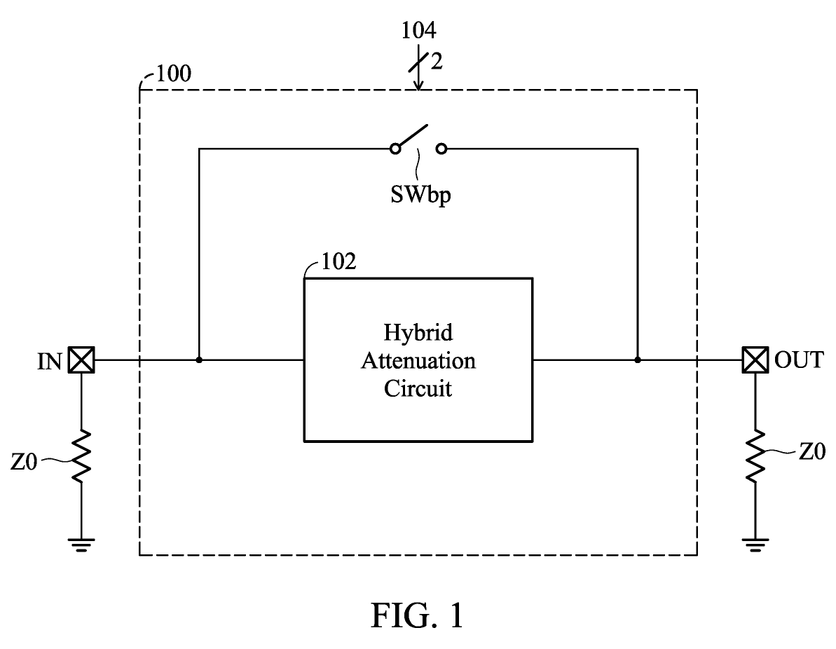

FIG. 1 depicts a multi-level digital step attenuator (DSA) 100 in accordance with an exemplary embodiment of the disclosure.

The multi-level DSA 100 has a hybrid attenuation circuit 102 and a bypass switch SWbp. The hybrid attenuation circuit 102 is coupled between an input node IN and an output node OUT of the multi-level DSA 100. The bypass switch SWbp is controlled to provide a bypass path between the input node IN and the output node OUT of the multi-level DSA 100 when the hybrid attenuation circuit 102 is in a disabled state. When the signal attenuation is enabled, the hybrid attenuation circuit 102 provides multiple options for effective signal attenuation. When being operated in a first active state, the hybrid attenuation circuit 102 is switched to form a T-type structure to provide a first amount of signal attenuation. When being operated in a second active state, the hybrid attenuation circuit 102 is switched to form a Pi-type structure to provide a second amount of signal attenuation.

In an exemplary embodiment, the multi-level DSA 100 is controlled by a 2-bit control signal 104 to switch the hybrid attenuation circuit 102 between the disabled state, the first active state, and the second active state. A 1.5-bit DSA is shown. In comparison with the conventional DSA design which requires a long series of DSAs to provide the multiple options for effective signal attenuation, the proposed multi-level DSA reduces the number of DSA stages. Fewer stages of DSAs are required for multi-level attenuation.

The impedance Z0 presented at the input node IN is the impedance of the former stage. The impedance Z0 presented at the output node OUT is the impedance of the next stage. The impedance of each electronic component of the hybrid attenuation circuit 102 depends on the attenuation target and the impedance Z0 of the former/next stage.

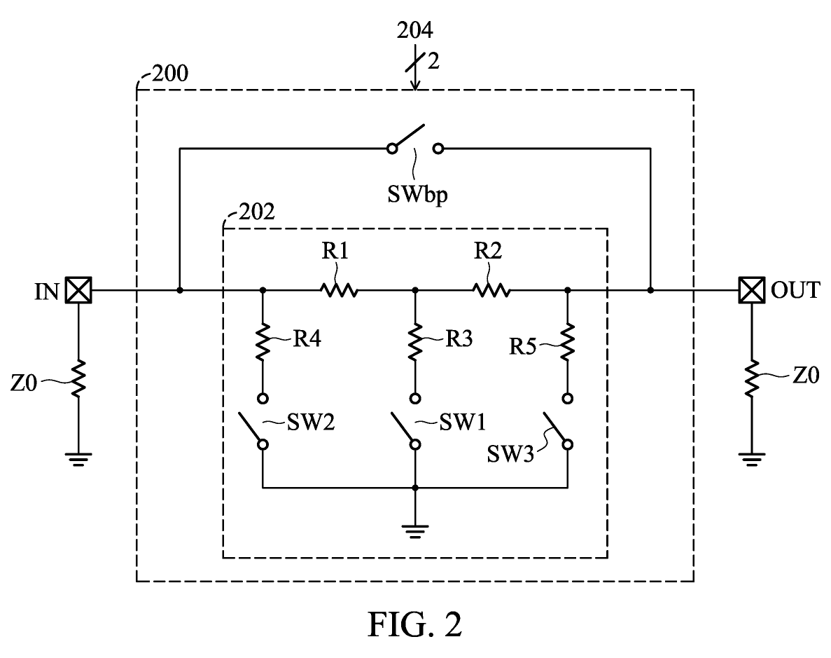

FIG. 2 depicts a multi-level DSA 200 in accordance with an exemplary embodiment of the disclosure.

The hybrid attenuation circuit 202 has a first resistor R1 and a second resistor R2 coupled in series between the input node IN and the output node OUT of the multi-level DSA 200. The hybrid attenuation circuit 202 further has a third resistor R3. When the switch SW1 is turned on to operate the hybrid attenuation circuit 202 in the first active state, the third resistor R3 couples a connection node between the first resistor R1 and the second resistor R2 to a ground terminal. The first, second, and third resistors R1, R2, and R3 form a T-type structure that generates the first amount of signal attenuation.

The hybrid attenuation circuit 202 further has a fourth resistor R4 and a fifth resistor R5. When the switches SW2 and SW3 are turned on to operate the hybrid attenuation circuit 202 in the second active state, the fourth resistor R4 is coupled between the input node IN of the multi-level DSA 200 and the ground terminal, and the fifth electronic component R5 is coupled between the output node OUT of the multi-level DSA 200 and the ground terminal. The first, second, fourth and fifth resistors R1, R2, R4, and R5 form a Pi-type structure that generates the second amount of signal attenuation.

In an exemplary embodiment, the multi-level DSA 200 is controlled by a 2-bit control signal 204. By controlling the 2-bit control signal 204, the switches SW1, SW2, and SW3 can be turned off, and the bypass switch SWbp can be turned on to operate the hybrid attenuation circuit 202 in its disabled state. When the switch SW1 is turned on, and the switches SW2 and SW3 are turned off with the bypass switch SWbp by the 2-bit control signal 204, the hybrid attenuation circuit 202 operates in its first active state to form the T-type structure to provide the first amount of signal attenuation. When the switches SW2 and SW3 are turned on, and the switch SW1 is turned off with the bypass switch SWbp by the 2-bit control signal 204, the hybrid attenuation circuit 202 operates in its second active state to form the Pi-type structure to provide the second amount of signal attenuation.

The first amout of signal attenuation may be 2^n dB, but not limited thereto. In the other exemplary embodiments, the first amout of signal attenuation may be any attenuation of non-radix-2.

In an exemplary embodiment, the T-type structure formed by the first, second, and third resistors R1, R2, and R3 provides signal attenuation of 2^n dB. For example, the impedance Z0 may be 50 ohm, the first resistor R1 and the second resistor R2 each may have a resistance of 36 ohm, and the third R3 may have a resistance of 16 ohm. The T-type structure formed by the first, second, and third resistors R1, R2, and R3 provides signal attenuation of 16 dB (=2^4 dB). In another exemplary embodiment, with the 36 ohm resistors R1 and R2 and the 50 ohm Z0, the fourth and the fifth resistors R4 and R5 each has a resistance of 96 ohm. The Pi-type structure formed by the first, second, fourth, and fifth resistors R1, R2, R4, and R5 provides signal attenuation of 10 dB (attenuation of non-radix-2). The detailed resistance values may be replaced by the other values, depending on the user’s needs.

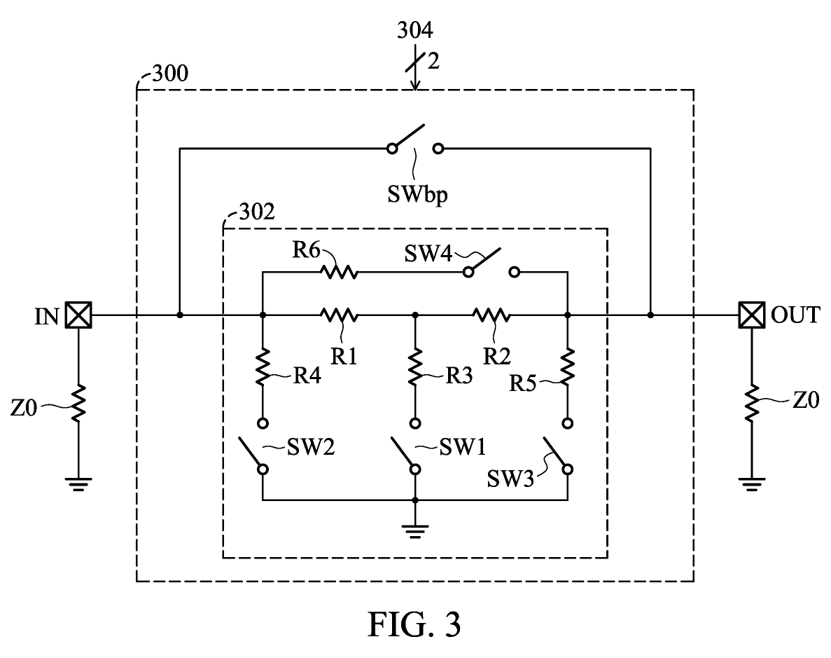

FIG. 3 depicts a multi-level DSA 300 in accordance with another exemplary embodiment of the disclosure. The hybrid attenuation circuit 302 further includes a sixth resistor R6 in comparison with the hybrid attenuation circuit 202. When the switch SW4 is turned on with the switches SW2 and SW3 to operate the hybrid attenuation circuit 302 in its second active state, the sixth resistor R6 is coupled between the input node IN and the output node OUT of the multi-level DSA 300, to being in parallel with the series of first and second resistors R1 and R2. The first, second, fourth, fifth, and sixth resistors R1, R2, R4, R5, and R6 also form a Pi-type structure that generates another amount of signal attenuation.

In an exemplary embodiment wherein the T-type structure (formed by the first, second, and third resistors R1, R2, and R3) provides signal attenuation of 2^n dB, the Pi-type structure (formed by first, second, fourth, fifth, and sixth resistors R1, R2, R4, R5, and R6) provides signal attenuation of 2^(n-1) dB. It is convenient to digital design.

In an exemplary embodiment, with the 36 ohm resistors R1 and R2, 16 ohm resistor R3, and the 50 ohm Z0, the fourth and the fifth resistors R4 and R5 each has a resistance of 116 ohm. Not only the T-type structure formed by the first, second, and third resistors R1, R2, and R3 provides 16dB signal attenuation that is in a power of 2, the Pi-type structure formed by the first, second, fourth, fifth, and sixth resistors R1, R2, R4, R5, and R6 provides signal attenuation of 8 dB, which is also in a power of 2.

In an exemplary embodiment, the multi-level DSA 300 is controlled by a 2-bit control signal 304. To switch the hybrid attenuation circuit 302 to its disabled state, the switches SW1, SW2, and SW3 are turned off, and the bypass switch SWbp is turned on by the 2-bit control signal 304. To switch the hybrid attenuation circuit 302 to its first active state to form the T-type structure to provide the first amount of signal attenuation, the switch SW1 is turned on, and the switches SW2, SW3 and SW4 are turned off with the bypass switch SWbp by the 2-bit control signal 304. To switch the hybrid attenuation circuit 302 to its second active state to form the Pi-type structure to provide the second amount of signal attenuation, the switches SW2, SW3 and SW4 are turned on, and the switch SW1 is turned off with the bypass switch SWbp by the 2-bit control signal 304.

In the other exemplary embodiments, the resistors used in the hybrid attenuation circuit 202/302 may be replaced by other types of electronic components. Any attenuation circuit capable of being switched to form a T-type structure in a first active state and form a Pi-type structure in a second state should be considered within the scope of the disclosure.

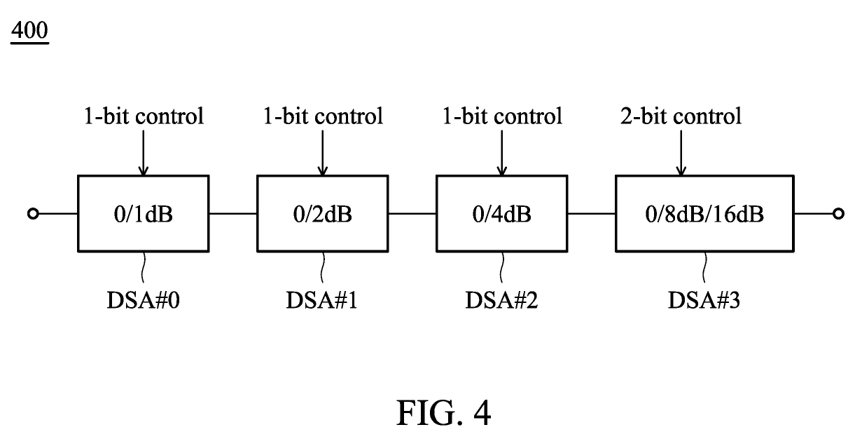

FIG. 4 depicts a digital step attenuation device 400 in accordance with an exemplary embodiment of the disclosure, which includes 4 stages of digital step attenuation units DSA#0, DSA#1, DSA#2, and DSA#3. The digital step attenuation unit DSA#3 in the final stage is the proposed multi-level DSA 300, that is capable of providing signal attenuation of 8dB or 16dB. The digital step attenuation unit DSA#0 in the number 0 stage is capable of providing signal attenuation of 1 dB (=2^0 dB). The digital step attenuation unit DSA#1 in the number 1 stage is capable of providing signal attenuation of 2 dB (=2^1 dB). The digital step attenuation unit DSA#2 in the number 2 stage is capable of providing signal attenuation of 4 dB (=2^2 dB). The first three digital step attenuation units DSA#0 to DSA#2 each is controlled by a 1-bit control signal. The final digital step attenuation unit DSA#3 is controlled by a 2-bit control signal. In such a design, the digital step attenuation device 400 can generate 24-level signal attenuation from 0dB to 23dB according to a 5-bit control signal. It is more attenuation levels in comparison with a conventional 4-stage digital step attenuation device that only provides 16-level signal attenuation from 0dB to 15dB.

In a conventional design, signal attenuation of 20dB requires 5 stages of conventional digital step attenuation units. However, the 20dB attenuation can be successfully achieved by the 4-stage digital step attenuation device 400. The fewer LC matching networks for impedance matching are used in the fewer stage design, which results in the improved circuit area efficiency, and the reduced insertion loss.

In an exemplary embodiment, a digital step attenuation device includes m stages of digital step attenuation units, and the stages are numbered from 0 to (m-1), where m is any positive integer greater than 1. At least one digital step attenuation unit in the m stages is implemented by the multi-level DSA 100.

In an exemplary embodiment, the digital step attenuation unit implemented by the multi-level DSA 100 is in the number (m-1) stage (e.g., the final stage as FIG. 4). When the multi-level DSA 100 in the number (m-1) stage is switched to its T-type structure, it provides signal attenuation of 2^m dB. When the multi-level DSA 100 in the number (m-1) stage is switched to its Pi-type structure, it provides signal attenuation of 2^(m-1) dB. The digital step attenuation units in the number 0 to the number (m-2) stages are capable of providing signal attenuation of 2^0 dB to 2^(m-2) dB, respectively. In such a design, the m-stage digital step attenuation device is capable of providing more than 2^m attenuation levels. The fewer LC matching networks are required in comparison with the conventional (m+1)-stage digital step attenuation device that is designed to provide more than 2^m attenuation levels.

Any digital step attenuation device using at least one of the proposed multi-level DSA 100 should be considered within the scope of the disclosure.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A multi-level digital step attenuator, comprising:
an input node and an output node;
a hybrid attenuation circuit, coupled between the input node and the output node; and
a bypass switch, controlled to provide a bypass path between the input node and the output node when the hybrid attenuation circuit is in a disabled state;
wherein the hybrid attenuation circuit comprises a series circuit portion coupled between the input node and the output node;
wherein in a first active state, the hybrid attenuation circuit is switched to form a T-type structure by the series circuit portion and a first shunt unit to provide a first amount of signal attenuation;
wherein in a second active state, the hybrid attenuation circuit is switched to form a Pi-type structure by the series circuit portion and a second shunt unit to provide a second amount of signal attenuation; and
wherein the first active state and the second active state share the series circuit portion as a signal attenuation path.

2. The multi-level digital step attenuator as claimed in claim 1, wherein the series circuit portion comprises a first electronic component and a second electronic component coupled in series between the input node and the output node.

3. The multi-level digital step attenuator as claimed in claim 2, wherein the first shunt unit comprises a third electronic component, coupling a connection node between the first electronic component and the second electronic component to a ground terminal in the first active state.

4. The multi-level digital step attenuator as claimed in claim 3, wherein the second shunt unit comprises a fourth electronic component and a fifth electronic component, wherein in the second active state, the fourth electronic component is coupled between the input node and the ground terminal, and the fifth electronic component is coupled between the output node and the ground terminal.

5. The multi-level digital step attenuator as claimed in claim 4, wherein the hybrid attenuation circuit further comprises a sixth electronic component, coupled between the input node and the output node in the second active state and connected in parallel with the first electronic component and the second electronic component.

6. The multi-level digital step attenuator as claimed in claim 5, wherein the first, second, third, fourth, fifth, and sixth electronic components are resistors.

7. The multi-level digital step attenuator as claimed in claim 1, wherein the first amount of signal attenuation is 2^n dB, and the second amount of signal attenuation is 2^(n-1) dB, where n is a positive integer.

8. The multi-level digital step attenuator as claimed in claim 1, controlled by a 2-bit control signal to switch the hybrid attenuation circuit between the disabled state, the first active state, and the second active state.

9. The multi-level digital step attenuator as claimed in claim 1, wherein the hybrid attenuation circuit and the bypass switch are integrated as a single 1.5-bit attenuation stage.

10. A digital step attenuation device, comprising:
multiple stages of digital step attenuation units,
wherein at least one digital step attenuation unit in the multiple stages is implemented by the multi-level digital step attenuator as claimed in claim 1.

11. The digital step attenuation device as claimed in claim 10, wherein:
the multiple stages of digital step attenuation units comprise m stages numbered from 0 to (m-1), where m is a positive integer greater than 1; and
the digital step attenuation unit implemented by the multi-level digital step attenuator is in the number (m-1) stage.

12. The digital step attenuation device as claimed in claim 11, wherein:
the digital step attenuation unit in the number (m-1) stage is controlled by a 2-bit control signal to provide three attenuation states, and each of the digital step attenuation units in stages 0 to (m-2) is controlled by a 1-bit control signal;
thereby the digital step attenuation device provides more than 2^m attenuation levels using only m stages to achieve stage reduction while maintaining attenuation resolution.
